(19) United States
(12) Patent Application Publication
(10) Pub. No.: US 2007/0126483 A1
(43) Pub. Date: Jun. 7, 2007

(54) Gate driver

(76) Inventor: Wei-Ming Chen, Kaohsiung City (TW)

Correspondence Address: J.C. Patents, Inc., Suite 250, 4 Venture, Irvine, CA, 92618, US

(21) Appl. No.: 11/340,170

(22) Filed: Jan. 25, 2006

(30) Foreign Application Priority Data
Dec. 2, 2005 (TW) 94142427

(51) Int. Cl. H03B 1/00

(52) U.S. Cl. 327/108

(57) ABSTRACT

A gate driver is disclosed. The gate driver includes a plurality of output circuits and a plurality of delay circuits. Each output circuit includes a start-up terminal. An output terminal of each delay circuit is coupled to an input terminal of a next delay circuit. The input terminal of the first delay circuit receives an enable signal. An output terminal of each delay circuit is coupled to a start-up terminal of one of the output circuits to activate the output circuits.

### CROSS-REFERENCE TO RELATED APPLICATION

This application claims the priority benefit of Taiwan application serial no. 94142427, filed on Dec. 2, 2005. All disclosure of the Taiwan application is incorporated herein by reference.

### BACKGROUND OF THE INVENTION

1. Field of Invention

The present invention relates to a device for driving a flat panel display, and more particularly, to a gate driver of the flat panel display.

2. Description of Related Art

The flat panel display, e.g., the liquid crystal display, has been widely used in recent years. With advance of semiconductor technology, the liquid crystal display has been endowed with various advantages, such as, low power consumption, compactness and light weight, high resolution, high color saturation, and long lifespan; thus, it is widely applied to electronic products closely associated with daily life, such as the liquid crystal screen of a notebook computer or desktop computer, and the liquid crystal display television (LCD TV). The gate driver of the display is an indispensable element of the liquid crystal display.

Generally speaking, the gate driver typically has a function referred to as the “all high function.” This function is generally used for discharging all the pixel capacitors when a liquid crystal display/liquid crystal display panel is turned off. FIG. 1A depicts a circuit block diagram of a conventional gate driver. FIG. 1B depicts a clock diagram of the conventional gate driver of FIG. 1A. In FIG. 1A, the gate driver 10 includes a plurality of output circuits 100, and each of the output circuits 100 includes a start-up terminal EN for receiving an enable signal OA. When the enable signal OA, for example, is converted from a logic high potential to a logic low potential, since all the start-up terminals EN of the output circuits 100 receive the enable signal OA, the all high function will be activated. The output terminals OG[1]-OG[N] of each output circuit 100 all output the logic high potentials to control thin film transistors of a control panel to be turned on.

As can be seen from the above circuit diagram of FIG. 1A and the clock diagram of FIG. 1B, when the all high function is activated, the gate driver supplies a large current to charge the liquid crystal panel, which results in a large required current supplied by the driving circuit and the power circuit. Accordingly, the gate driver may be damaged, or a larger occupied layout chip area of the integrated circuit is required for maintaining the all high function.

### SUMMARY OF THE INVENTION

An object of the present invention is to provide a gate driver for preventing the unnecessary power consumption caused by an all high function of the gate driver and reducing the occupied layout chip area of an integrated circuit.

Here is provided a gate driver, which includes a plurality of output circuits and a plurality of delay circuits. Each output circuit includes a start-up terminal. An output terminal of each delay circuit is coupled to an input terminal of a next delay circuit. The input terminal of the first delay circuit receives an enable signal. An output terminal of each delay circuit is coupled to a start-up terminal of one of the output circuits for sequentially enabling these output circuits.

Since a plurality of delay circuits are implemented by the present invention in order for delaying the enable signal, when the all high function is activated, the gate driver does not need to drive a large load at the instantaneous moment that the enable signal is enabled, and the panel system does not provide a large current for charging the liquid crystal panel. Therefore, not only the current of the panel, but also the occupied layout chip area of the integrated circuit is reduced so as to prevent the risk of the gate driver being damaged.

To make the aforementioned and other objects, features and advantages of the present invention comprehensible, a preferred embodiment accompanied with figures is described in detail below.

### BRIEF DESCRIPTION OF THE DRAWINGS

FIG. 1A is a circuit block diagram of a conventional gate driver;

FIG. 1B is a clock diagram of the operation of the conventional gate driver of FIG. 1A;

FIG. 2 is a circuit block diagram of a gate driver according to an embodiment of the present invention;

FIG. 3 is a clock diagram of the operation of the circuit in FIG. 2 according to an embodiment of the present invention; and

FIGS. 4 and 5 are circuit diagrams for implementing the delay circuit in the gate driver according to an embodiment of the present invention.

### DESCRIPTION OF EMBODIMENTS

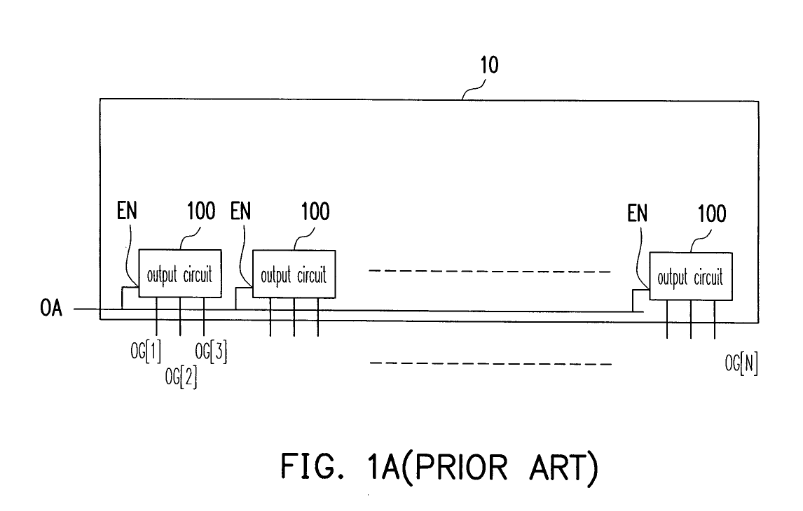

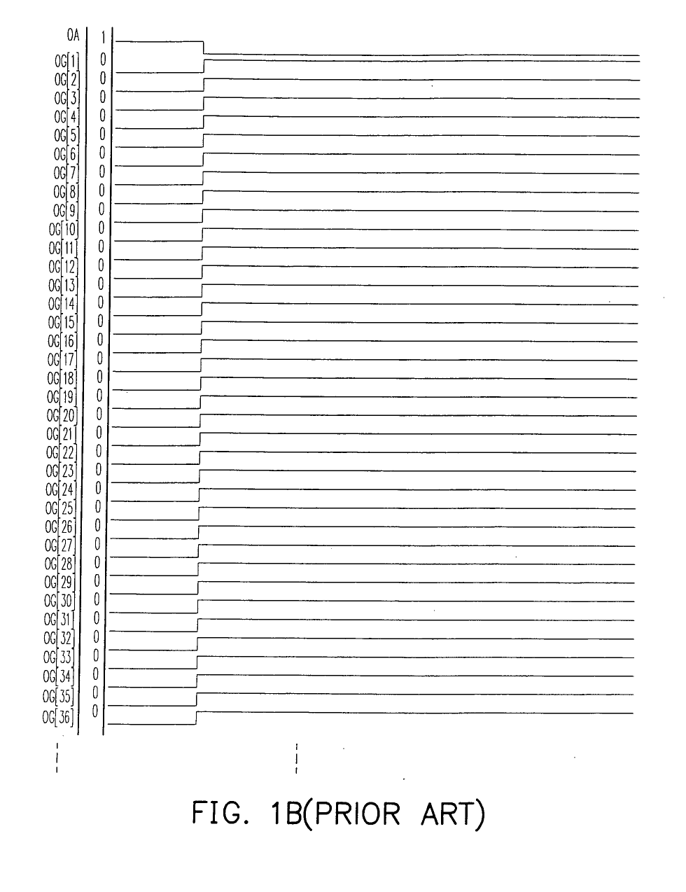

Since a result as shown in FIG. 1B occurs in the prior art, the instantaneous current output from the gate driver is very large when the all high function has been activated. The present invention will be illustrated below through embodiments of the present invention in order for overcoming the conventional drawbacks.

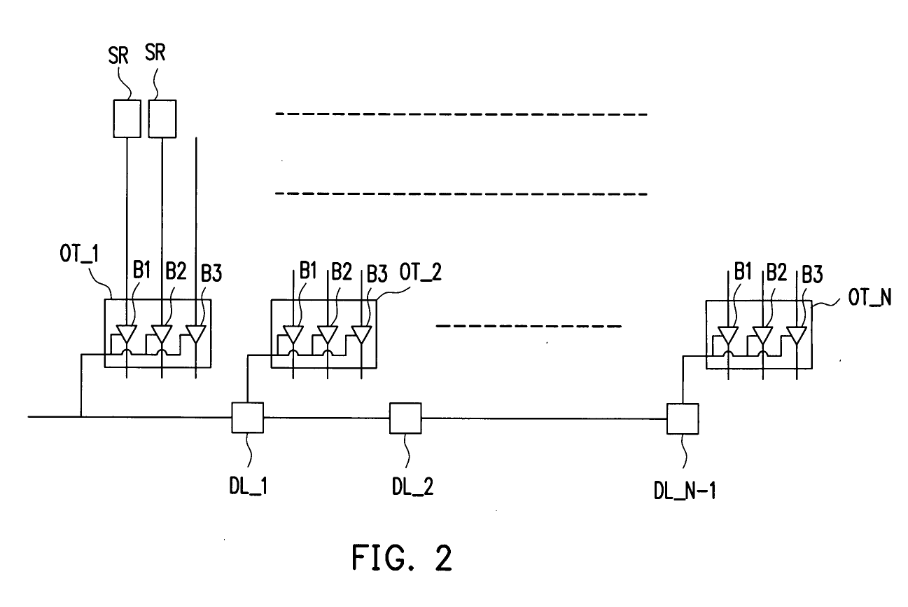

FIG. 2 is a circuit block diagram of a gate driver according to an embodiment of the present invention. Referring to FIG. 2, the gate driver includes a plurality of output circuits OT_1-OT_N, a plurality of delay circuits DL_1-DL_N-1, and a plurality of shift registers SR. The delay circuits DL_1-DL_N-1 are coupled to each other in such a manner that the output terminal of one delay circuit is connected in series to the input terminal of a next one. In addition, the output terminals of each delay circuit 202 are further coupled to the corresponding start-up terminals of the output circuits OT_1-OT_N respectively, in order to sequentially enable these output circuits OT_1-OT_N. In this embodiment, each of the output circuits OT_1-OT_N includes three output buffers B1-B3, however, the present invention is not limited to that.

When the gate driver circuit is in an normal operation, the shift registers SR starts to sequentially output the signals to the output buffers B1-B3 of the output circuits OT_1-OT_N in order to drive the liquid crystal display according to the scanning order of the scanning line.

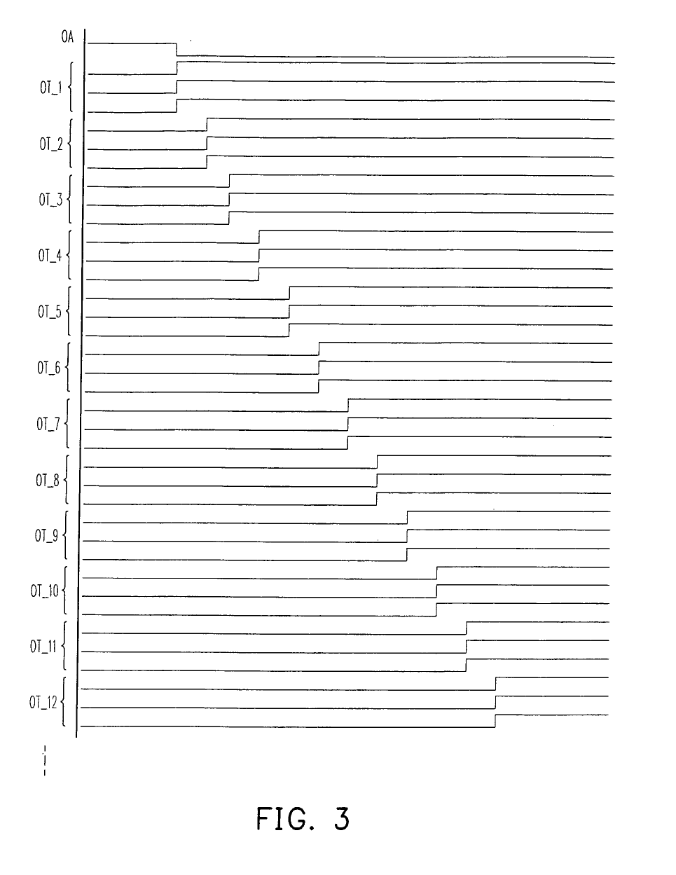

FIG. 3 is a clock diagram of the operation of the circuit in FIG. 2 according to an embodiment of the present invention. Then, referring to FIG. 3 and FIG. 2 concurrently in order to make a comparison thereof, when the all high function is activated, the first delay circuit DL_1 and the first output circuit OT_1 receives the enable signal OA, and at this time the first output circuit OT_1 is enabled accordingly, such that the buffers B1-B3 therein output the high logic potential to turn on thin film transistors corresponding to the turn-on of the three scanning lines of the liquid crystal panel. Next, the enable signal OA is first delayed by the first delay circuit DL_1 for a preset time, and then output to the second delay circuit DL_2 and the second output circuit OT_2. Then, the following is the repetition of above operation.

As can be realized from the above explanation, when the all high function is activated, all the output circuits of the conventional gate driver output a high logic potential, thereby resulting in a large instantaneous current. However, in the embodiment of the present invention, since the output circuits OT_1-OT_N are activated in batches instead of being activated simultaneously, the large instantaneous current can be avoided at the moment that the all high function is activated.

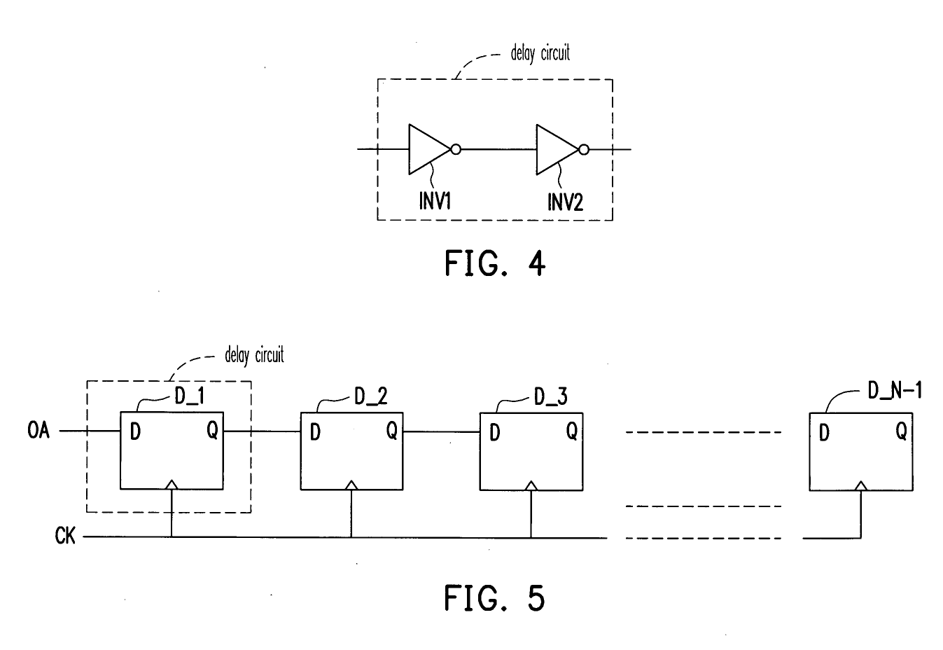

The above delay circuits DL_1-DL_N-1 can be implemented in many ways, for example, as shown in FIG. 4, a delay circuit consists of two inverters INV1 and INV2. A transmission delay between the first inverter INV1 and the second inverter INV2 acts is implemented as the preset time, and the enable signal OA is delayed for the preset time after it is transferred through an every stage of delay circuits. In addition, the delay circuits also can be implemented in such a way as shown in FIG. 5, wherein, a series of D-type triggers D_1-D_N-1 are utilized, and the enable signal OA is received by an input terminal of the first D-type trigger D_1 and is transferred to the next D-type trigger by every clock time CK.

In summary, since the plurality of delay circuits are employed by the present invention for delaying the enable signal, when the all high function is activated, the gate driver does not need to drive a large load at the instantaneous moment that the enable signal is enabled, and the panel system doesn't provide a large current for charging the liquid crystal panel. Therefore, not only the current of the panel, but also the occupied layout chip area of the integrated circuit is reduced, and the risk of the gate driver being damaged can be removed as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A gate driver for preventing an over large instantaneous current when an all high function is activated, comprising:
a plurality of output circuits, each of which comprises a start-up terminal; and
a plurality of delay circuits, each of which comprises an output terminal coupled to an input terminal of a next delay circuit, wherein, the input terminal of the first delay circuit receives an enable signal, and the output terminals of each delay circuit are further coupled to the start-up terminals of the corresponding output circuits, respectively, in order for sequentially enabling the output circuits.

2. The gate driver as claimed in claim 1, wherein each of the delay circuits comprises:
a first inverter, comprising a first input terminal and a first output terminal, wherein the first input terminal receives the enable signal, and the enable signal is output after being logically inverted; and
a second inverter, comprising a second input terminal and a second output terminal, wherein the second input terminal is coupled to the first output terminal of the first inverter, and the enable signal output from the first output terminal of the first inverter is output after being logically inverted.

3. The gate driver as claimed in claim 1, wherein each of the delay circuits comprises:
a D-type trigger, comprising an input terminal, an output terminal, and a clock input terminal, wherein the input terminal is the input terminal of the delay circuit, the clock input terminal receives a clock signal and the output terminal is the output terminal of the delay circuit.

4. The gate driver as claimed in claim 1, wherein each of the output circuits comprises:
an output buffer, comprising a control terminal coupled to the start-up terminal of the output circuit for starting up the output buffer.

5. The gate driver as claimed in claim 1, wherein each of the output circuits comprises:
a plurality of output buffers, each of which comprises a control terminal coupled to the start-up terminal of the output circuit for starting up the output buffer.
